(19) United States
(12) Patent Application Publication
(10) Pub. No.: US 2014/0070321 A1
(43) Pub. Date: Mar. 13, 2014

(54) INTEGRATED CIRCUITS HAVING BORON-DOPED SILICON GERMANIUM CHANNELS AND METHODS FOR FABRICATING THE SAME

(71) Applicants: Martin Gerhardt, Dresden (DE); Stefan Flachowsky, Dresden (DE); Matthias Kessler, Dresden (DE)

(72) Inventors: Martin Gerhardt, Dresden (DE); Stefan Flachowsky, Dresden (DE); Matthias Kessler, Dresden (DE)

(73) Assignee: GLOBALFOUNDRIES INC., Grand Cayman (KY)

(21) Appl. No.: 13/613,190

(22) Filed: Sep. 13, 2012

(51) Int. Cl. H01L 27/088; H01L 21/20

(52) U.S. Cl. 257/368; 438/478; 257/E21.09; 257/E27.06

(57) ABSTRACT

Integrated circuits and methods for fabricating integrated circuits are provided. One method includes recessing a PFET active region to form a recessed PFET surface region. A boron-doped SiGe channel is formed overlying the recessed PFET surface region.

### TECHNICAL FIELD

The technical field relates generally to integrated circuits and methods for fabricating integrated circuits, and more particularly relates to integrated circuits having boron-doped SiGe channels and methods for fabricating such integrated circuits.

### BACKGROUND

Transistors such as metal oxide semiconductor field effect transistors (MOSFETs) or simply field effect transistors (FETs) or MOS transistors are the core building blocks of the vast majority of semiconductor integrated circuits (ICs). A FET includes a gate electrode as a control electrode overlying a semiconductor substrate and spaced apart source and drain regions in the substrate between which a current can flow. A gate insulator is disposed between the gate electrode and the semiconductor substrate to electrically isolate the gate electrode from the substrate. A control voltage applied to the gate electrode controls the flow of current through a channel in the substrate underlying the gate electrode between the source and drain regions. The ICs are usually formed using both P-channel FETs (PMOS transistors or PFETs) and N-channel FETs (NMOS transistors or NFETs) and the IC is then referred to as a complementary MOS or CMOS circuit.

There is a continuing trend to incorporate more and more circuitry on a single IC chip. To incorporate the increasing amount of circuitry, the size of each individual device in the circuit and the size and spacing between device elements (the feature size) must decrease. To achieve scaling of semiconductor devices, a variety of unconventional and/or “exotic” materials are being contemplated. High dielectric constant materials, also referred to as “high-k dielectrics,” such as hafnium silicon oxynitride (HfSiON) and hafnium zirconium oxide (HfZrOx), among others, are considered for the 45 nm technology node and beyond to allow scaling of gate insulators. To prevent Fermi-level pinning, metal gates with the proper work function are used as gate electrodes on the high-k dielectrics. Such metal gate electrodes typically are formed of a metal gate-forming material such as lanthanum (La), aluminum (Al), magnesium (Mg), ruthenium (Ru), titanium-based materials such as titanium (Ti) and titanium nitride (TiN), tantalum-based materials such as tantalum (Ta) and tantalum nitride (TaN) or tantalum carbide (Ta₂C), or the like.

In high-k/metal-gate technologies, silicon germanium (SiGe) may be used to form channels for PFETs to enhance electron mobility in the channels and reduce the threshold voltage (V(t)) of the transistors. However, SiGe as a channel material has a few drawbacks. In particular, the V(t) shift of the PFET is a function of the Ge content and thickness of the SiGe channel. The higher the weight percent (wt. %) of Ge in the SiGe channel the lower the PFET V(t), and the thicker the SiGe channel the lower the PFET V(t). Unfortunately, the interface trap density of the SiGe channel increases with higher wt. % of Ge resulting in higher leakage current and reduced current density. Additionally, if the SiGe channel becomes relatively thick, the channel can show signs of plastic stress relaxation, which detrimentally affects the PFET's functionality.

Accordingly, it is desirable to provide integrated circuits (e.g., including high-k/metal-gate technologies) with PFET channels that help enhance electron mobility in the channels and reduce the V(t) of the transistors without substantially increasing leakage current, reducing current density, and/or detrimentally affecting the functionality of the PFETs, and methods for fabricating such integrated circuits. Furthermore, other desirable features and characteristics of the present invention will become apparent from the subsequent detailed description and the appended claims, taken in conjunction with the accompanying drawings and the foregoing technical field and background.

### BRIEF SUMMARY

Methods for fabricating integrated circuits are provided herein. In accordance with an exemplary embodiment, a method for fabricating an integrated circuit includes recessing a PFET active region to form a recessed PFET surface region. A boron-doped SiGe channel is formed overlying the recessed PFET surface region.

In accordance with another exemplary embodiment, a method for fabricating an integrated circuit is provided. The method includes masking a NFET active region with a hard mask. A PFET active region is etched to form a recessed PFET surface region. A boron-doped SiGe channel is epitaxially grown overlying the recessed PFET surface region.

In accordance with another exemplary embodiment, an integrated circuit is provided. The integrated circuit includes a PFET active region and a boron-doped SiGe channel formed in the PFET active region. A gate electrode structure is formed above the boron-doped SiGe channel. Source and drain regions are formed in the PFET active region adjacent to the boron-doped SiGe channel.

### BRIEF DESCRIPTION OF THE DRAWINGS

The various embodiments will hereinafter be described in conjunction with the following drawing figures, wherein like numerals denote like elements, and wherein:

FIGS. 1-7 illustrate methods for fabricating integrated circuits having boron-doped SiGe channels in accordance with various embodiments. FIGS. 1-7 illustrate the integrated circuit in cross sectional views during various stages of its fabrication.

### DETAILED DESCRIPTION

The following Detailed Description is merely exemplary in nature and is not intended to limit the various embodiments or the application and uses thereof Furthermore, there is no intention to be bound by any theory presented in the preceding background or the following detailed description.

Various embodiments contemplated herein relate to integrated circuits with improved PFET channels, and methods for fabricating such integrated circuits. In accordance with one embodiment, during early stages of the fabrication of an integrated circuit (IC), a PFET active region of a semiconductor substrate is recessed, e.g., via wet or dry etching, to form a recessed PFET surface region. A boron-doped SiGe channel is formed overlying the recessed PFET surface region. In an exemplary embodiment, the SiGe channel is in-situ doped with boron during a selective epitaxial growth process. A gate electrode structure is formed above the boron-doped SiGe channel. In an exemplary embodiment, the gate electrode structure is a metal gate electrode structure and includes a high-k dielectric layer, a P-type work function metal layer, and metal gate material layer. Source and drain regions are formed in the PFET active region adjacent to the boron-doped SiGe channel. It has been found that the SiGe channel doped with a relatively small amount of boron (e.g., a boron doping level of from about 1.0×10¹⁸ to about 1.0×10¹⁹ boron atoms/cm³) helps enhance electron mobility in the channel and further reduces the V(t) of the transistor while the channel thickness and wt. % of Ge in the channel are maintained within ranges that do not substantially increase the interface trap density or detrimentally affect the functionality of the PFETs.

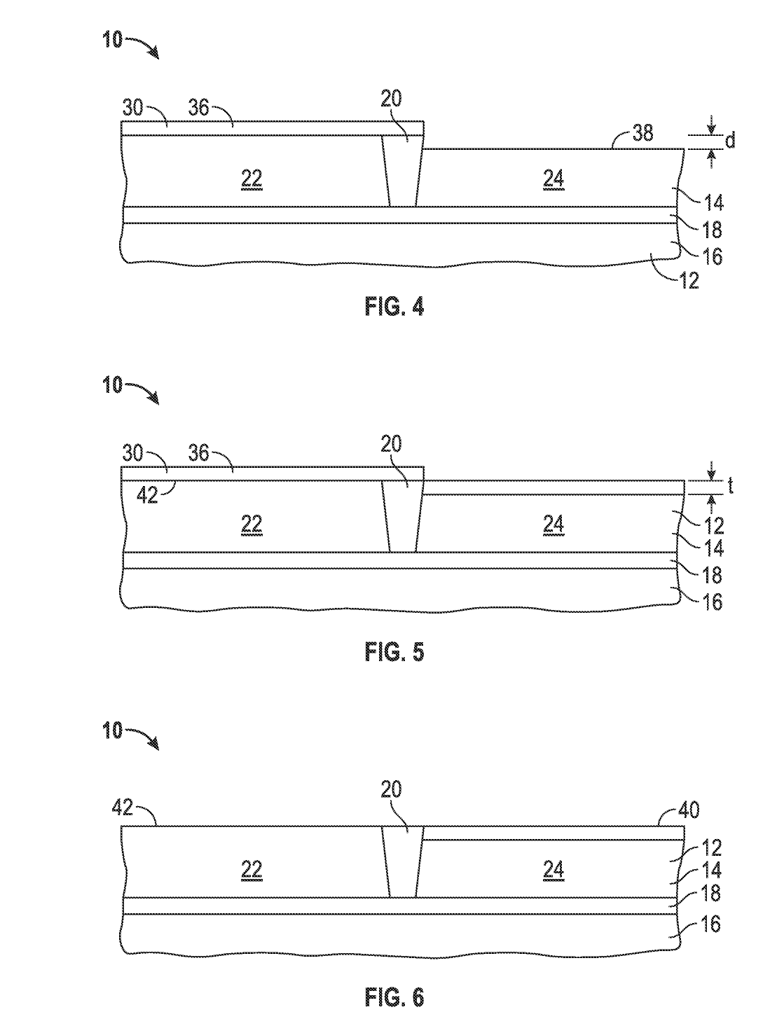

FIGS. 1-7 illustrate methods for fabricating an IC 10 in accordance with various embodiments. The described process steps, procedures, and materials are to be considered only as exemplary embodiments designed to illustrate to one of ordinary skill in the art methods for practicing the invention; the invention is not limited to these exemplary embodiments. Various steps in the fabrication of ICs are well known and so, in the interest of brevity, many conventional steps will only be mentioned briefly herein or will be omitted entirely without providing the well known process details.

FIG. 1 illustrates, in cross sectional view, a portion of the IC 10 at an early stage of fabrication in accordance with an exemplary embodiment. The IC 10 includes a semiconductor substrate 12. As illustrated, the semiconductor substrate 12 represents a silicon-on-insulator (SOI) having a semiconductor layer 14, a silicon substrate 16, and a buried insulating layer 18. The semiconductor layer 14 may be formed of a substantially crystalline semiconductor material, such as silicon, silicon/germanium, or any other silicon-based material known to those skilled in the art. The silicon substrate 16 may be formed of a substantially crystalline silicon substrate material that may be doped or undoped in accordance with device requirements. The buried insulating layer 18 separates the semiconductor layer 14 and the silicon substrate 16 and is formed of an insulating material, such as silicon oxide or the like.

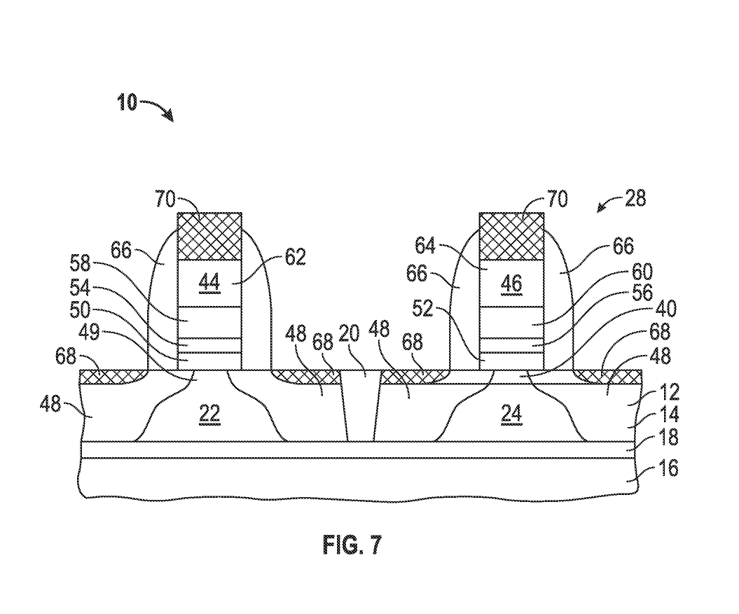

In an exemplary embodiment, an isolation structure 20 (e.g., shallow trench isolation STI) is provided in the semiconductor layer 14. The isolation structure 20 defines corresponding NFET and PFET active regions 22 and 24, which are to be understood as a semiconductor regions having formed therein and/or receiving an appropriate dopant profile as required for forming transistor elements. The NFET and PFET active regions 22 and 24 correspond to the active regions of transistors 26 and 28 (see FIG. 7), which represent an N-channel transistor and a P-channel transistor, respectively.

The IC 10 as shown in FIG. 1 may be formed on the basis of the following exemplary processes. After providing the semiconductor substrate 12, the isolation structure 20 is formed using lithography, etch, deposition, planarization techniques and the like. Next, the basic doping of the NFET and PFET active regions 22 and 24 is established, for instance, by ion implantation.

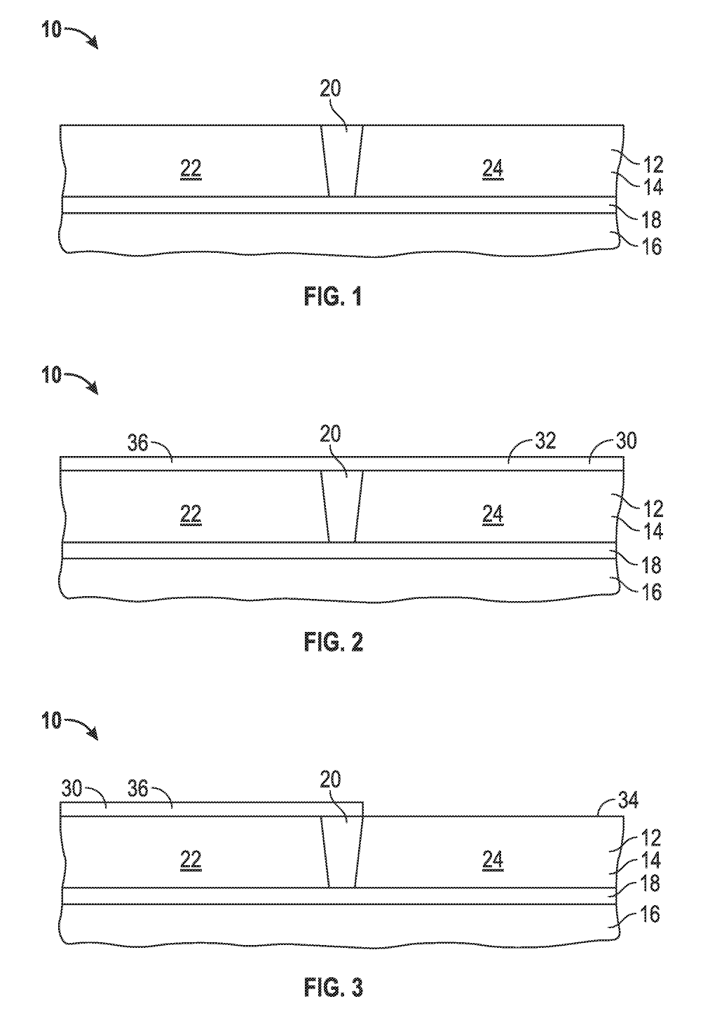

FIGS. 2-4 illustrate, in cross sectional views, the IC 10 at further advanced fabrication stages in accordance with an exemplary embodiment. A hard mask layer 30 is formed overlying the NFET and PFET active regions 22 and 24. In an exemplary embodiment, the hard mask layer 30 is formed by depositing silicon oxide or silicon nitride, for example, using well known process techniques, such as chemical vapor deposition (CVD) or the like.

The portion 32 of the hard mask layer 30 overlying the PFET active region 24 is selectively removed with an etchant, such as hydrochloric acid (HF) or other oxide etchant if the hard mask layer 30 is formed of silicon oxide, to expose a surface 34 of the PFET active region 24. A portion 36 of the hard mask layer 30 remains to protectively cover or mask the NFET active region 22.

The process continues by recessing the PFET active region 24 to form a recessed PFET surface region 38. As illustrated, the PFET active region 24 is recessed to a depth (indicated by single headed arrows “d”) to allow a subsequently-deposited silicon-based material channel, i.e., a boron-doped SiGe channel 40, to achieve a height approximately equal to the height of a surface 42 of the NFET active region 22. In an exemplary embodiment, the depth “d” is from about 5 to about 10 nm. The recessed PFET surface region 38 may be formed by exposing the surface 34 of the PFET active region 24 to a dry etching process and/or a wet etching process. For example, the recessed PFET surface region 38 may be formed on the basis of a substantially anisotropic etch behavior on the basis of a plasma assisted etch, while, in other cases, the recessed PFET surface region 38 may be formed by wet chemical etch chemistries, which may have a crystallographic anisotropic etch behavior, or on the basis of a combination of plasma assisted etch and wet chemical etch chemistries.

FIGS. 5-6 illustrate, in cross sectional views, the IC 10 at further advanced fabrication stages in accordance with an exemplary embodiment. A boron/silicon/germanium composition is deposited and/or grown on the recessed PFET surface region 38 of the PFET active region 24 to form the boron-doped SiGe channel 40. In an exemplary embodiment, the boron-doped SiGe channel 40 is formed via a selective epitaxial growth process. As a result of epitaxially growing the boron-doped SiGe channel 40, boron is in-situ doped into the channel 40 with SiGe. In one example, the boron-doped SiGe channel 40 is epitaxially grown using a low pressure chemical vapor deposition (LPCVD) process.

In an exemplary embodiment, the boron-doped SiGe channel 40 has a boron doping level of from about 1.0×10¹⁸ to about 1.0×10¹⁹ boron atoms/cm³, for example, from about 2.5×10¹⁸ to about 7.5×10¹⁸ boron atoms/cm³. In one embodiment, it has been found that forming the boron-doped SiGe channel 40 having a boron doping level of at least about 1.0×10¹⁸ helps enhance electron mobility in the channel 40 and reduce the V(t) of the transistor 28 (see FIG. 7) while a boron doping level of greater than about 1.0×10¹⁹ boron atoms/cm³ can result in undesirable leakage current. In another embodiment, the boron-doped SiGe channel 40 is formed having a germanium content of from about 23 to about 30 wt. % of the boron-doped SiGe channel to limit the interface trap density of the boron-doped SiGe channel 40 to limit leakage current and maintain current density. In an exemplary embodiment, the boron-doped SiGe channel 40 is formed having a thickness (indicated by single headed arrows “t”) of from about 5 to about 10 nm to minimize or prevent any detrimental effect to the functionality of the transistor 28 (see FIG. 7).

The process continues as illustrated in FIG. 6 by removing the portion 36 of the hard mask layer 30 overlying the NFET active region 22. As discussed above, the hard mask layer 30 may be removed with an etchant, such as an oxide etchant, to expose the surface 42 of the NFET active region 22.

FIG. 7 illustrates, in cross sectional views, the IC 10 at a further advanced fabrication stage in accordance with an exemplary embodiment. The transistors 26 and 28 include corresponding gate electrode structures 44 and 46. In an exemplary embodiment, the gate electrode structures 44 and 46 are configured as metal gate electrode structures that are formed using a high-k/metal-gate gate-first-approach process, which forms the gate electrode structures 44 and 46 before forming source and drain regions 48. As illustrated, the gate electrode structures 44 and 46 include high-k dielectric layers 50 and 52 overlying the NFET and PFET active regions 22 and 24, respectively. The high-k dielectric layers 50 and 52 separate the remaining portions of gate electrode structures 44 and 46 from their corresponding channels 49 and 40. The high-k dielectric layers 50 and 52 may be formed of HfSiON, HfZrOx, or any other high-k dielectric material known to those skilled in the art.

Correspondingly overlying the high-k dielectric layers 50 and 52 are N-type and P-type work function metal layers 54 and 56. In an exemplary embodiment, the N-type work function metal layer 54 is formed of TaC, TiC, or the like, and the P-type work function metal layer 56 is formed of TiN or the like. Disposed over the N-type and P-type work function metal layers 54 and 56 are metal gate material layers 58 and 60, respectively. The metal gate material layers 58 and 60 may be formed of a conductive metal, such as tungsten (W) or the like. Polysilicon layers 62 and 64 are formed correspondingly overlying the metal gate material layers 58 and 60.

The transistors 26 and 28 include sidewall spacers 66 that are formed along the gate electrode structures 44 and 46. The source and drain regions 48 are formed in the semiconductor layer 14 laterally adjacent to the gate electrode structures 44 and 46, and metal silicide regions 68 and 70 are formed in the respective transistors 26 and 28. In particular, the metal silicide regions 68 are formed in the semiconductor layer 14 laterally offset from the respective channels 40 and 49 and are used for forming device contacts with the source and drain regions 48 of the transistors 26 and 28 as is well known in the art.

The IC 10 as shown in FIG. 7 may be formed on the basis of the following exemplary processes. After forming the boron-doped SiGe channel 40 as discussed above, the process continues by forming the gate electrode structures 44 and 46 including the high-k dielectric layers 50 and 52, the N-type and the P-type work function metal layers 54 and 56, the metal gate material layers 58 and 60, and the polysilicon layers 62 and 64 on the basis of deposition, patterning, and etching techniques. The sidewall spacers 66 are formed along the gate electrode structures 44 and 46 on the basis of oxidation and/or deposition techniques. The sidewall spacers 66 are further defined in accordance with process and device requirements so as to act as an implantation mask, at least at various fabrication stages of the implantation sequences, to establish the desired vertical and lateral dopant profiles for the source and drain regions 48 and the desired offset to the channels 40 and 49. It should be appreciated that respective implantation processes have to be performed differently for transistors of different conductivity types. That is, respective resist masks may be provided prior to a specific ion implantation process to prevent unwanted dopant species from being introduced into specific transistor elements. Thereafter, one or more annealing processes may be performed to activate the dopants. The process continues by forming the metal silicide regions 68 and 70 by depositing a refractory metal, such as, for example, cobalt, nickel, titanium, tantalum, platinum, palladium, and/or rhodium, and subsequently performing one or more heat treatments to initiate a chemical reaction to form metal silicide.

Accordingly, integrated circuits and methods for fabricating integrated circuits have been described. In accordance with one embodiment, during early stages of the fabrication of an integrated circuit (IC), a PFET active region of a semiconductor substrate is recessed to form a recessed PFET surface region. A boron-doped SiGe channel is formed overlying the recessed PFET surface region. It has been found that the SiGe channel doped with a relatively small amount of boron helps enhance electron mobility in the channel and further reduce the V(t) of the transistor while the channel thickness and wt. % of Ge in the channel are maintained within ranges that do not substantially increase the interface trap density or detrimentally affect the functionality of the PFETs.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

1. A method for fabricating an integrated circuit, the method comprising:
recessing a PFET active region to form a recessed PFET surface region; and
forming a boron-doped SiGe channel overlying the recessed PFET surface region.

2. The method of claim 1, wherein forming the boron-doped SiGe channel comprises forming the boron-doped SiGe channel having a boron doping level of at least about 1.0×10¹⁸ boron atoms/cm³.

3. The method of claim 1, wherein forming the boron-doped SiGe channel comprises forming the boron-doped SiGe channel having a boron doping level of from about 1.0×10¹⁸ to about 1.0×10¹⁹ boron atoms/cm³.

4. The method of claim 1, wherein forming the boron-doped SiGe channel comprises forming the boron-doped SiGe channel having a boron doping level of from about 2.5×10¹⁸ to about 7.5×10¹⁸ boron atoms/cm³.

5. The method of claim 1, wherein forming the boron-doped SiGe channel comprises forming the boron-doped SiGe channel having a thickness of from about 5 to about 10 nm.

6. The method of claim 1, wherein forming the boron-doped SiGe channel comprises forming the boron-doped SiGe channel having a germanium content of from about 23 to about 30 wt. % of the boron-doped SiGe channel.

7. The method of claim 1, wherein forming the boron-doped SiGe channel comprises performing a selective epitaxial growth process to grow the boron-doped SiGe channel in-situ doped with boron.

8. The method of claim 7, wherein forming the boron-doped SiGe channel comprises performing the selective epitaxial growth process using a low pressure chemical vapor deposition (LPCVD) process.

9. The method of claim 1, further comprising:
forming a gate electrode structure above the boron-doped SiGe channel.

10. A method for fabricating an integrated circuit, the method comprising:
masking a NFET active region with a hard mask;
etching a PFET active region to form a recessed PFET surface region;
epitaxially growing a boron-doped SiGe channel overlying the recessed PFET surface region.

11. The method of claim 10, further comprising:
removing the hard mask from the NFET active region;
depositing a first high-k dielectric layer overlying the NFET active region and a second high-k dielectric layer overlying the boron-doped SiGe channel;
depositing a N-type work function metal layer overlying the first high-k dielectric layer;
depositing a P-type work function metal layer overlying the second high-k dielectric layer; and
forming a first metal gate material layer and a second metal gate material layer overlying the N-type and P-type work function metal layers, respectively.

12. The method of claim 10, wherein epitaxially growing the boron-doped SiGe channel comprises forming the boron-doped SiGe channel having a boron doping level of at least about 1.0×10¹⁸ boron atoms/cm³.

13. The method of claim 12, wherein epitaxially growing the boron-doped SiGe channel comprises forming the boron-doped SiGe channel having the boron doping level of about 1.0×10¹⁹ boron atoms/cm³ or less.

14. The method of claim 10, wherein epitaxially growing the boron-doped SiGe channel comprises forming the boron-doped SiGe channel having a boron doping level of from about 2.5×10¹⁸ to about 7.5×10¹⁸ boron atoms/cm³.

15. The method of claim 10, wherein epitaxially growing the boron-doped SiGe channel comprises forming the boron-doped SiGe channel having a thickness of from about 5 to about 10 nm.

16. The method of claim 10, wherein epitaxially growing the boron-doped SiGe channel comprises forming the boron-doped SiGe channel having a germanium content of from about 23 to about 30 wt. % of the boron-doped SiGe channel.

17. An integrated circuit comprising:
a PFET active region;
a boron-doped SiGe channel formed in the PFET active region;
a gate electrode structure formed above the boron-doped SiGe channel; and
source and drain regions formed in the PFET active region adjacent to the boron-doped SiGe channel.

18. The integrated circuit of claim 17, wherein the boron-doped SiGe channel has a boron doping level of at least about 1.0×10¹⁸ boron atoms/cm³.

19. The integrated circuit of claim 17, wherein the boron-doped SiGe channel has a thickness of from about 5 to about 10 nm.

20. The integrated circuit of claim 17, wherein the boron-doped SiGe channel has a germanium content of from about 23 to about 30 wt. % of the boron-doped SiGe channel.
